(19) United States
(12) Patent Application Publication
(10) Pub. No.: US 2014/0077814 A1
(43) Pub. Date: Mar. 20, 2014

(54) METHOD AND SYSTEM FOR TESTING MATRICES AND METHOD FOR CONTROLLING VOLTAGE CLOCKS

(71) Applicant: CHICONY ELECTRONICS CO., LTD., New Taipei (TW)

(72) Inventor: Chin-Cheng Tseng, New Taipei (TW)

(73) Assignee: CHICONY ELECTRONICS CO., LTD., New Taipei (TW)

(21) Appl. No.: 13/747,296

(22) Filed: Jan. 22, 2013

(30) Foreign Application Priority Data
Sep. 14, 2012 (TW) 101133636

(51) Int. Cl. G01R 31/327

(52) U.S. Cl. CPC G01R 31/327
USPC 324/415

(57) ABSTRACT

The present invention discloses method and system for testing matrices and method for controlling voltage clocks, comprising the steps of: providing a matrix circuit comprising a plurality of first end points and a plurality of second end points, wherein there is a path having a switch thereon between each of the first end points and a corresponding one of the second end points; supplying pulse voltages to the first end points or the second end points in accordance with a time sequence, wherein each of the pulse voltages has a given time width and there is no temporal overlap between the pulse voltages; and determining whether or not each of the switches functions properly through simultaneous depressing of more than one of the switches and on the basis of the amounts of time for which respective pulse voltages function at the first end points or the second end points.

### CROSS-REFERENCE TO RELATED APPLICATION

This non-provisional application claims priority under 35 U.S.C. §119(a) on Patent Application No. 101133636 filed in Taiwan (R.O.C.) on Sep. 14, 2012, the entire contents of which are hereby incorporated by reference.

### BACKGROUND OF THE INVENTION

1. Field of the Invention

The present invention relates to a method for controlling clocks, and more particularly, to method and system for testing matrices, which are capable of increasing the efficiency in testing matrices, and method for controlling voltage clocks.

2. Description of the Prior Art

Nowadays, computers and electronic facilities have been widely used at home and at work, and a keyboard is one of the important tools for inputting control commands or data thereinto. Therefore, the quality and performance of a keyboard directly affect whether computers and electronic facilities can be stably and accurately operated. For a keyboard, its keys are directly operated elements, thus the test on keys is important for computers and electronic facilities.

Conventionally, a keyboard is designed by a key matrix structure in order to reduce the number of connection lines arranged between the keyboard and the computer. During the process of testing a keyboard, when a plurality of keys are depressed simultaneously, it may be unable to identify the input signal of a single key due to the physical characteristics of the key matrix, or the physical characteristics of the key matrix per se cause the ghost key phenomenon, resulting in an invalid test.

FIG. 1 is a schematic representation showing a standard 2×2 key matrix 100 of a prior art keyboard. The causes of the ghost key phenomenon will be detailed by reference to FIG. 1. The key matrix 100 includes four keys, implemented as a double cross structure and corresponding to the membrane switch elements SW1-SW4, respectively. Each one of the four membrane switch elements SW₁-SW₄ has a first node and a second node. When a key corresponding to a membrane switch element (e.g., SW₁) is depressed, the first node thereof will contact with the second node thereof, and the membrane switch element will be turned on, thereby making the scan line X₁ turned on with the return line Y₁. Therefore, it can be known whether the key corresponding to the membrane switch element SW₁ is currently depressed according to the signal at the return line Y₁. When the key corresponding to the membrane switch element is not depressed, the first node thereof will not contact with the second node thereof, and the membrane switch element is turned off. Therefore, there is no signal transmitted at the return line Y₁.

Because of the physical characteristics of the above-mentioned key matrix 100, when any three of the keys corresponding to the switch elements SW₁-SW₄ are depressed, even if the remaining key is not depressed, the system will make an erroneous judgment that the remaining key has been depressed, where the remaining key is the so-called ghost key. To more specifically describe the ghost key phenomenon, please refer to FIG. 2A through FIG. 2D, which illustrate the possible causes of the ghost key phenomenon at the key matrix 100 shown in FIG. 1. As shown in FIG. 2A, when the switch elements SW₁-SW₃ are turned on, the scan line X₂ and the return line Y₂ will be turned on by another transmission path (i.e., the black thick line via the switch elements SW₁-SW₃), and the switch element SW₄ will also be turned on, leading to an erroneous judgment that the key corresponding to the switch element SW₄ is depressed (i.e., the ghost key phenomenon). Furthermore, as shown in FIG. 2B, when the switch elements SW₂-SW₄ are turned on by depressing the corresponding keys, the scan line X₁ and the return line Y₁ will be turned on by another transmission path provided by the switch elements SW₂-SW₄, leading to an erroneous judgment that the key corresponding to the switch element SW₁ is depressed. In addition, as shown in FIG. 2C, the scan line X₁ and the return line Y₂ will be turned on by another transmission path provided by the switch elements SW₁, SW₃, SW₄, leading to an erroneous judgment that the key corresponding to the switch element SW₂ is depressed. Moreover, as shown in FIG. 2D, when the scan line X₂ and the return line Y₁ are turned on, an erroneous judgment indicating that the key corresponding to the switch element SW₃ is depressed will be made.

In the past, whether individual keys function properly is usually determined by manually depressing each key or by avoiding simultaneous depressing of certain key combinations which may cause the ghost key phenomenon. Alternatively, the keyboard circuit is provided with additional devices, such as diode separation loop or voltage division resistor, to prevent the ghost key phenomenon. However, these methods are time-consuming and laborious, require an excessive investment of facilities and incur high labor costs. Accordingly, the efficiency of the aforementioned methods is not satisfactory.

Therefore, a need exists in the art for method and system for testing matrices, which are capable of increasing the efficiency in testing matrices, and method for controlling voltage clocks.

### SUMMARY OF THE INVENTION

In view of the aforementioned problems of the prior art, an object of the present invention is to provide method and system for testing matrices and method for controlling voltage clocks so as to solve the problem that the existing techniques for testing matrices are not satisfactory.

According to an object of the present invention, there is provided a method for testing matrices, comprising the steps of: providing a matrix circuit comprising a plurality of first end points and a plurality of second end points, wherein there is a path having a switch thereon between each one of the plurality of first end points and a corresponding one of the plurality of second end points; supplying pulse voltages to the plurality of first end points or the plurality of second end points in accordance with a time sequence, wherein each of the pulse voltages has a given time width and there is no temporal overlap between the pulse voltages; and determining whether each of the switches functions properly through simultaneous depressing of more than one of the switches and on the basis of the amounts of time for which respective pulse voltages function at the plurality of first end points or the plurality of second end points.

According to an object of the present invention, there is provided a system for testing matrices, comprising: a plurality of depressing elements; a pulse voltage generating unit; a matrix circuit comprising a plurality of first end points and a plurality of second end points, there being a path having a switch thereon between each one of the plurality of first end points and a corresponding one of the plurality of second end points; a processing module controlling the pulse voltage generating unit to sequentially supply pulse voltages to the plurality of first end points or the plurality of second end points, each of the pulse voltages having a given time width and there being no temporal overlap between the pulse voltages, the processing module controlling more than one of the plurality of depressing elements to simultaneously depress more than one of the switches and thereby to generate a depressing result; and a monitoring module determining whether each of the switches functions properly based on the depressing result and the amounts of time for which respective pulse voltages function at the plurality of first end points or the plurality of second end points.

According to an object of the present invention, there is provided a method for controlling voltage clocks for use in a matrix test system, comprising the steps of: providing a matrix circuit comprising a plurality of first end points and a plurality of second end points, wherein there is path having a switch thereon between each one of the plurality of first end points and a corresponding one of the plurality of second end points; and supplying pulse voltages to the plurality of first end points or the plurality of second end points in a sequential order, wherein each of the pulse voltages has a given time width and there is no temporal overlap between the pulse voltages.

The aforementioned aspects and other aspects of the present invention will be better understood with reference to the following exemplary embodiments and drawings.

### BRIEF DESCRIPTION OF THE DRAWINGS

FIG. 1 is a schematic representation showing a standard 2×2 key matrix 100 of a prior art keyboard.

FIGS. 2A-2D illustrates possible causes of the ghost key phenomenon at the key matrix 100 shown in FIG. 1.

FIG. 3 is a block diagram of a system for testing matrices in accordance with an embodiment of the present invention.

FIG. 4 is a schematic representation of a matrix circuit in accordance with an embodiment of the present invention.

FIG. 5A is a signal timing diagram of pulse voltages of a matrix test system in accordance with an embodiment of the present invention.

FIG. 5B is a signal detection timing diagram of a matrix test system in accordance with a first embodiment of the present invention.

FIG. 5C is a signal detection timing diagram of a matrix test system in accordance with a second embodiment of the present invention.

FIG. 6 is a flow chart of a method for testing matrices in accordance with an embodiment of the present invention.

FIG. 7 is a flow chart of a method for controlling voltage clocks in accordance with an embodiment of the present invention.

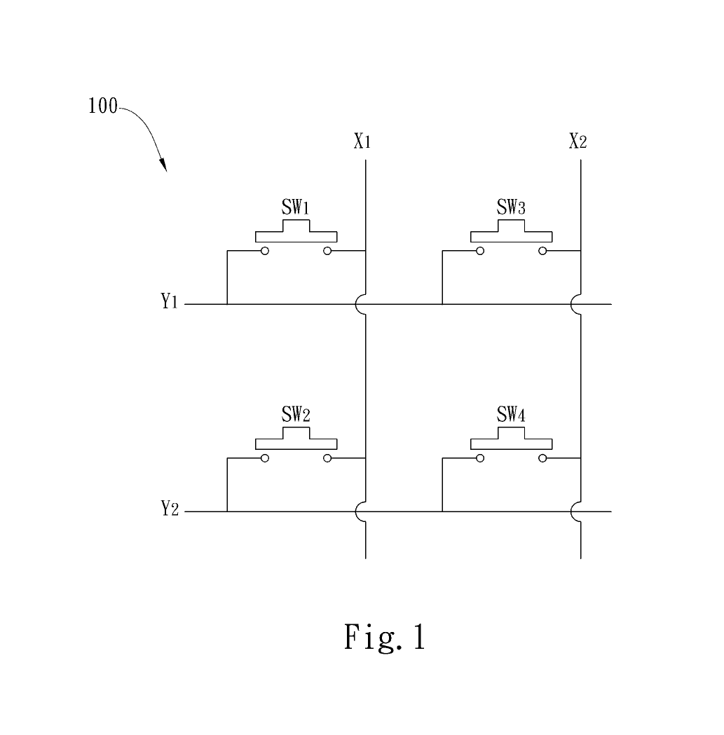

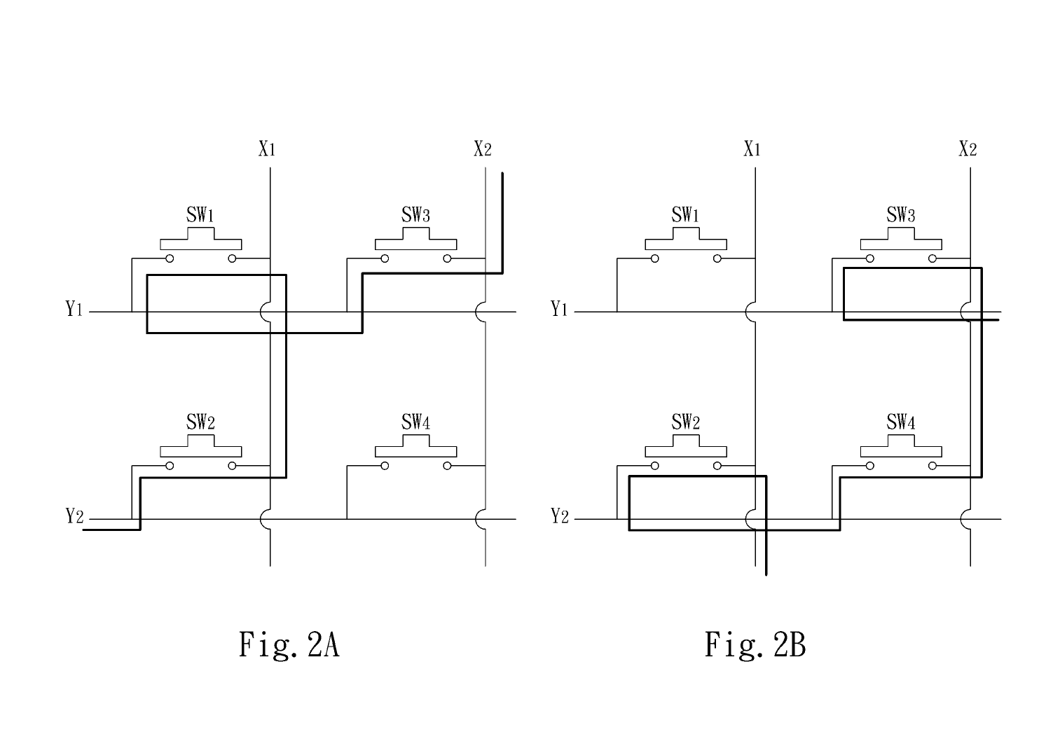

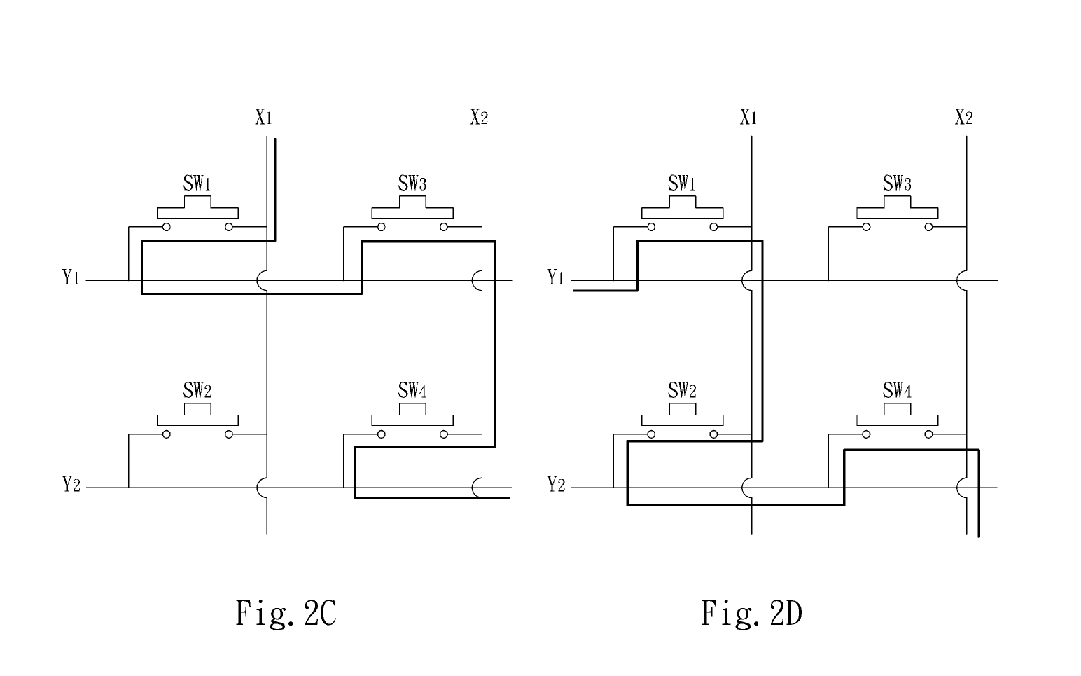

### DETAILED DESCRIPTION OF THE PREFERRED EMBODIMENTS

The present invention will be fully described by way of preferred embodiments and appended drawings to facilitate the understanding of the technical features, contents and advantages of the present invention. It will be understood that the appended drawings are merely schematic representations and may not be illustrated according to actual scale and precise arrangement of the implemented invention. Therefore, the present invention shall not be construed based on the scale and arrangement illustrated on the appended drawings, and the embodiments and appended drawings are not intended to limit the scope of protection of the present invention.

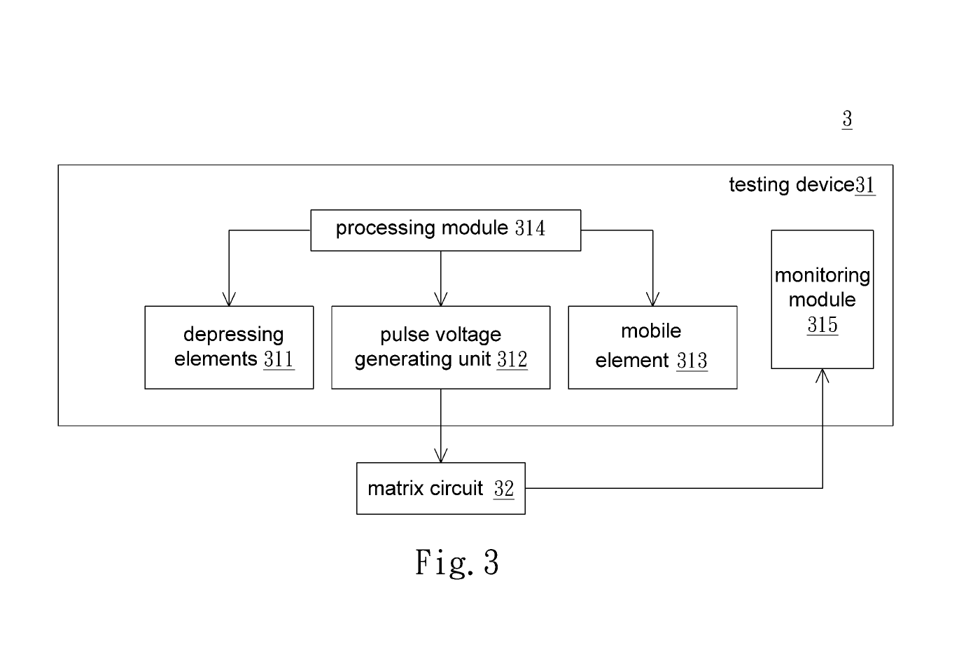

FIG. 3 is a block diagram of a system 3 for testing matrices in accordance with an embodiment of the present invention. As shown in FIG. 3, the system 3 for testing matrices of the present invention preferably comprises a testing device 31 and a matrix circuit 32. The testing device 31 preferably comprises a plurality of depressing elements 311, a pulse voltage generating unit 312, a mobile element 313, a processing module 314 and a monitoring module 315. The processing module 314 is preferably a Central Processing Unit (CPU) or a Micro-Processing Unit and can electrically connect the plurality of depressing elements 311, the pulse voltage generating unit 312 and the mobile element 313. The matrix circuit 32 may comprise a plurality of first end points having a first electric potential and a plurality of second end points having a second electric potential. Preferably, the first electric potential is a high voltage level and the second electric potential is a low voltage level. However, the present invention is not limited to the aforementioned arrangements in real practice. There is a path having a switch thereon between each one of the plurality of first end points and a corresponding one of the plurality of second end points.

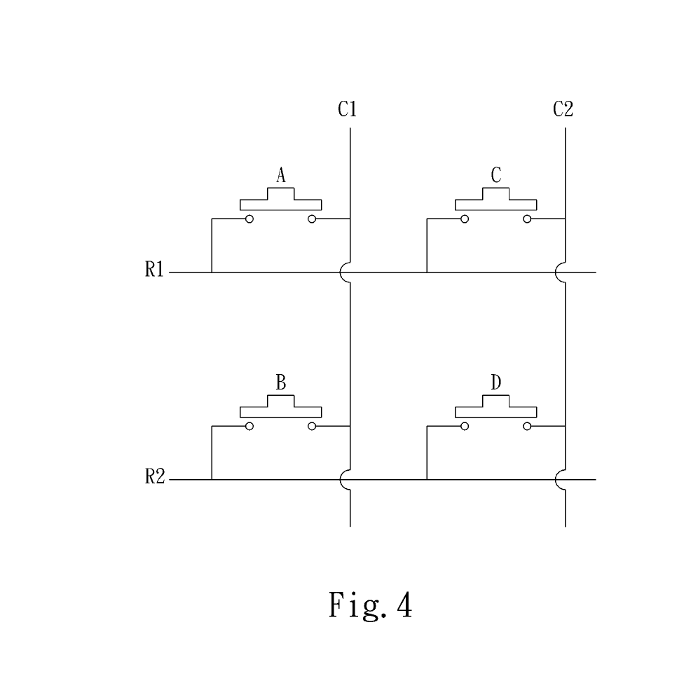

Moreover, the processing module 314 can control the mobile element 313 to move the matrix circuit 32 to a location to be tested. Next, the processing module 314 can further control the pulse voltage generating unit 312 to sequentially supply pulse voltages to the plurality of first end points or the plurality of second end points of the matrix circuit 32, wherein each of the pulse voltages has a given time width and there is no temporal overlap between the pulse voltages. The processing module 314 also controls more than one of the plurality of depressing elements 311 to simultaneously depress more than one of the switches to generate a depressing result at the same time. The monitoring module 315 can determine whether each of the switches functions properly based on the depressing result and the amounts of time for which respective pulse voltages function at the plurality of first end points or the plurality of second end points of the matrix circuit 32. FIG. 4 is a schematic representation of a matrix circuit in accordance with an embodiment of the present invention. In this embodiment, an exemplary 2×2 matrix circuit 32 is illustrated, as shown in FIG. 4. The matrix circuit 32 may comprise two Vcc (positive voltage) end points C1 and C2 and two ground points R1 and R2. Positive voltage end points C1 and C2 are connected respectively to the ground points R1 and R2, and the connecting paths therebetween have switches A, B, C and D thereon, respectively.

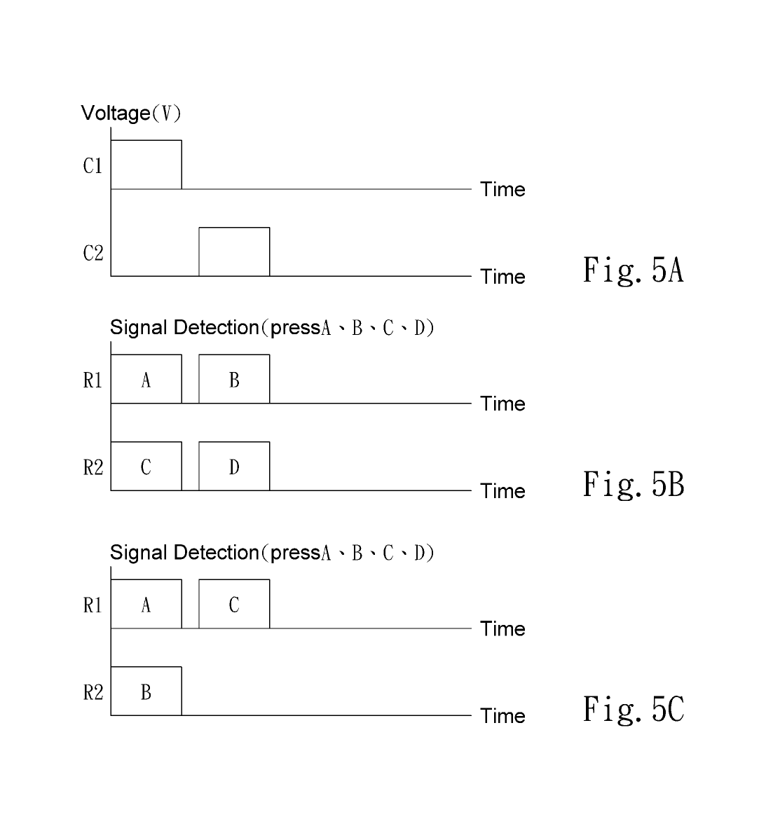

FIG. 5A is a signal timing diagram of pulse voltages of a matrix test system in accordance with an embodiment of the present invention. As shown in FIG. 5A, the processing module 314 can sequentially supply pulse voltages to Vcc (positive voltage) end points C1 and C2. In this embodiment, it is preferable that each of the pulse voltages has a given time width and there is no temporal overlap of the pulse voltages, and that these pulse voltages have given time intervals therebetween.

FIGS. 5B and 5C are signal detection timing diagrams of the matrix test system in accordance with a first embodiment and a second embodiment of the present invention, respectively. Referring to FIGS. 5B and 5C, the first and second embodiments demonstrate that the matrix test system can be preferably used in testing key matrix. Under the circumstance that the processing module 314 supplies a pulse voltage to the positive voltage end point C1, signals are supposed to be measured only from the lines between the positive voltage end point C1 and the ground points R1 and R2 when the four keys A, B, C and D are depressed simultaneously. Therefore, if no signal is measured from the line between the positive voltage end point C1 and the ground point R1, it can be determined that the key A does not function properly. Moreover, the same criterion, i.e. whether signals can be measured from the line between the positive voltage end point C1 and the ground point R2, can be used to determine the performance of the key B. Similarly, when the processing module 314 supplies a pulse voltage to the Vcc (positive voltage) end point C2, whether or not the keys C and D function properly can be determined easily.

That is, the multi-stage supply of pulse voltages enables the occurrence of a high voltage level and a low voltage level in an alternating manner (the use of different voltage levels and pulses). The pulse voltages are inputted from the positive voltage end points C1 and C2 of the key matrix. The time when the pulse voltage starts varies at different positive voltage end points. At any specific time, only one positive voltage end point is at the high voltage level while the other positive voltage end point is at the low voltage level. Next, the impedance value or voltage is measured at the ground points R1 and R2 of the key matrix, and whether or not a key is depressed is determined by whether the corresponding line is turned on. With known lines and data corresponding to the keys, any individual key can be identified easily to avoid an erroneous judgment. Even if a plurality of keys are depressed simultaneously and it is likely that the ghost key phenomenon may occur, the depressed key can be accurately identified because the On signals will not be measured simultaneously at the ground points R1 and R2 when pulse voltages are inputted from the positive voltage end points C1 and C2.

Those having ordinary knowledge in the art can understand that the exemplary 2×2 matrix circuit, the electric potentials of the end points C1, C2 and the ground points R1, R2 with respect to each other and the order in which the pulse voltages are supplied in multi stages are exemplary and are not intended to limit the present invention, and that any method or system without departing from the spirit and scope of the present matrix test system falls within the spirit of the present invention.

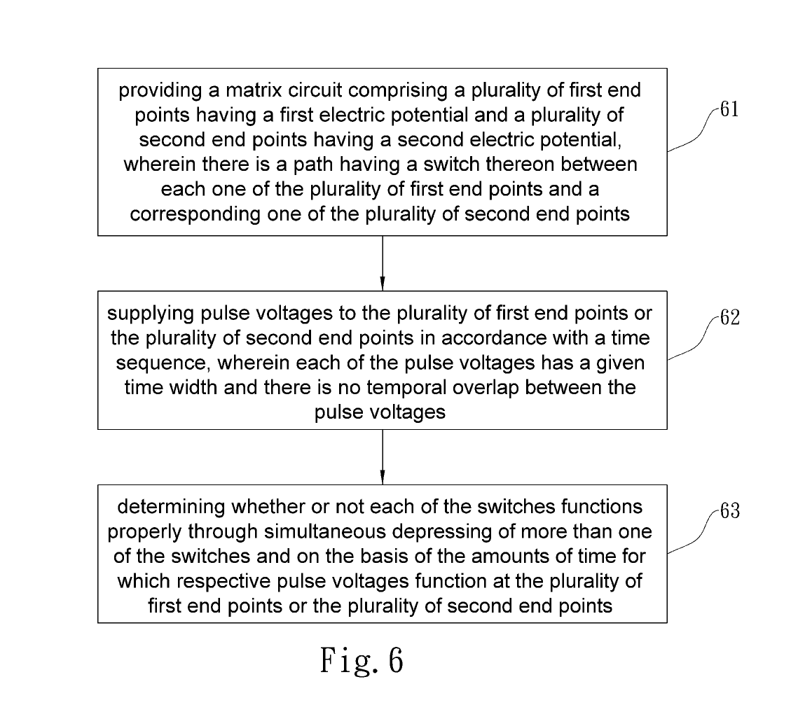

FIG. 6 is a flow chart of a method for testing matrices in accordance with an embodiment of the present invention. As shown in FIG. 6, the method for testing matrices can be used to test any device having matrix features, such as the keys of a keyboard, a membrane switch, or a touch panel, etc. In this embodiment, there is provided a method for testing matrices comprising the step (61) of providing a matrix circuit comprising a plurality of first end points having a first electric potential and a plurality of second end points having a second electric potential, wherein there is a path having a switch thereon between each one of the plurality of first end points and a corresponding one of the plurality of second end points; the step (62) of supplying pulse voltages to the plurality of first end points or the plurality of second end points in accordance with a time sequence, wherein each of the pulse voltages has a given time width and there is no temporal overlap between the pulse voltages; and the step (63) of determining whether or not each of the switches functions properly through simultaneous depressing of more than one of the switches and on the basis of the amounts of time for which respective pulse voltages function at the plurality of first end points or the plurality of second end points.

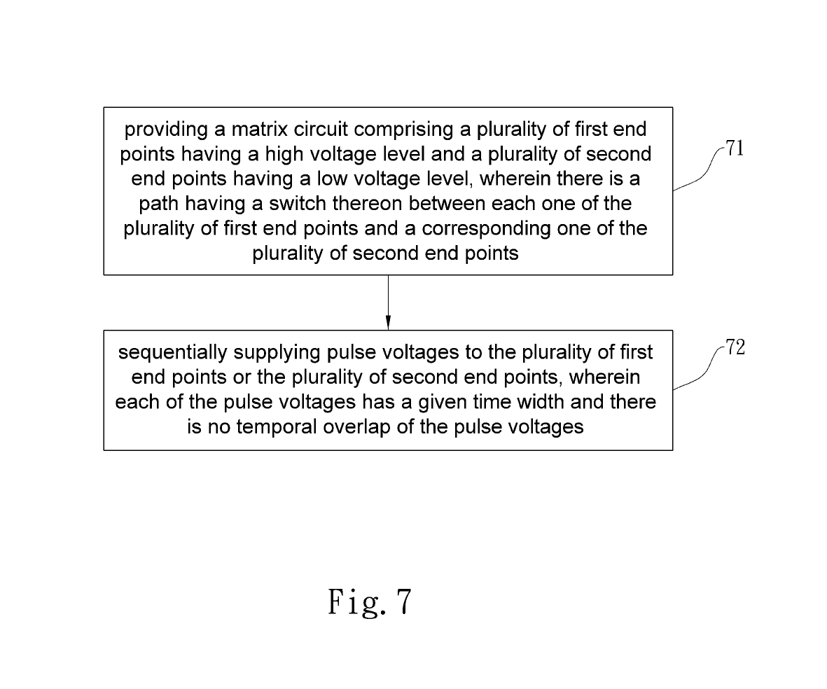

FIG. 7 is a flow chart of a method for controlling voltage clocks in accordance with an embodiment of the present invention. As shown in FIG. 7, the method for controlling voltage clocks can be used in controlling voltage clocks when the performance of a matrix apparatus is tested. In this embodiment, there is provided a method for controlling voltage clocks comprising the step (71) of providing a matrix circuit comprising a plurality of first end points having a high voltage level and a plurality of second end points having a low voltage level, wherein there is a path having a switch thereon between each one of the plurality of first end points and a corresponding one of the plurality of second end points; and the step (72) of sequentially supplying pulse voltages to the plurality of first end points or the plurality of second end points, wherein each of the pulse voltages has a given time width and there is no temporal overlap of the pulse voltages.

To sum up, the method and system for testing matrices and the method for controlling voltage clocks of the present invention enable simultaneous depressing of a plurality of keys of a keyboard and the identification of ghost keys by changing the test method without increasing the cost incurred by the parts of the keyboard. The present invention can increase the speed in testing a keyboard and reduce the production cost.

With the present invention, even if a plurality of keys are depressed simultaneously, individual keys can be identified and an erroneous judgment caused by the ghost key phenomenon can be prevented. Respective lines can be identified through the use of different voltage levels and the arrangement of time intervals provided the pulse voltages.

Moreover, the present invention can also be operated together with a force sensor and a key stroke logging method (optical scale, stepper motor, servomotor, etc.) to measure and record a D-F curve and to measure the amount of time required to turn on a key (location) of the key matrix by supplying pulse voltages to the positive voltage end points so as to determine unsatisfactory performance of a key concerning touch feelings, heavy depressing, sensitivity, self-conductivity, etc.

The embodiments depicted above are exemplary and are not intended to limit the scope of the present creation. Any change or alteration with equivalent efficiency made without departing from the spirit and scope of this invention fall within the scope of the appended claims.

What is claimed is:

1. A method for testing matrices comprising the steps of:
providing a matrix circuit comprising a plurality of first end points and a plurality of second end points, wherein there is a path having a switch thereon between each one of the plurality of first end points and a corresponding one of the plurality of second end points;
supplying pulse voltages to the plurality of first end points or the plurality of second end points in a time sequence, wherein each of the pulse voltages has a given time width and there is no temporal overlap between the pulse voltages; and
determining whether or not each of the switches functions properly through simultaneous depressing of more than one of the switches and on the basis of the amounts of time for which respective pulse voltages function at the plurality of first end points or the plurality of second end points.

2. The method for testing matrices according to claim 1, wherein the plurality of first end points have a first electric potential and the plurality of second end points have a second electric potential.

3. The method for testing matrices according to claim 2, wherein the first electric potential is a high voltage level and the second electric potential is a low voltage level.

4. The method for testing matrices according to claim 1, wherein the pulse voltages have given time intervals therebetween.

5. A system for testing matrices, comprising:
a plurality of depressing elements;
a pulse voltage generating unit;
a matrix circuit comprising a plurality of first end points and a plurality of second end points, there being a path having a switch thereon between each one of the plurality of first end points and a corresponding one of the plurality of second end points;
a mobile element moving the matrix circuit to a location to be tested;
a processing module controlling the pulse voltage generating unit to sequentially supply pulse voltages to the plurality of first end points or the plurality of second end points, each of the pulse voltages having a given time width and there being no temporal overlap between the pulse voltages, the processing module controlling more than one of the plurality of depressing elements to simultaneously depress more than one of the switches so as to generate a depressing result; and
a monitoring module determining whether or not each of the switches functions properly on the basis of the depressing result and the amounts of time for which respective pulse voltages function at the plurality of first end points or the plurality of second end points.

6. The system for testing matrices according to claim 5, wherein the plurality of first end points have a first electric potential and the plurality of second end points have a second electric potential.

7. The system for testing matrices according to claim 6, wherein the first electric potential is a high voltage level and the second electric potential is a low voltage level.

8. The system for testing matrices according to claim 5, wherein the pulse voltages have given time intervals therebetween.

9. A method for controlling voltage clocks for a matrix test comprising the steps of:
providing a matrix circuit comprising a plurality of first end points and a plurality of second end points, wherein there being a path having a switch thereon between each one of the plurality of first end points and a corresponding one of the plurality of second end points; and
supplying pulse voltages to the plurality of first end points or the plurality of second end points in a sequential order, wherein each of the pulse voltages has a given time width and there is no temporal overlap between the pulse voltages.

10. The method for controlling voltage clocks according to claim 9, wherein the plurality of first end points have a first electric potential and the plurality of second end points have a second electric potential.

11. The method for controlling voltage clocks according to claim 10, wherein the first electric potential is a high voltage level and the second electric potential is a low voltage level.

12. The method for controlling voltage clocks according to claim 9, wherein the pulse voltages have given time intervals therebetween.
